(19) United States
(12) Patent Application Publication
(10) Pub. No.: US 2015/0085571 A1
(43) Pub. Date: Mar. 26, 2015

(54) UPDATING READ VOLTAGES

(71) Applicant: SANDISK TECHNOLOGIES INC., Plano, TX (US)

(72) Inventors: Xinde HU, San Diego, CA (US); Nian Niles YANG, Mountain View, CA (US); Uday CHANDRASEKHAR, San Jose, CA (US); Jianmin HUANG, San Carlos, CA (US)

(73) Assignee: SANDISK TECHNOLOGIES INC., Plano, TX (US)

(21) Appl. No.: 14/035,749

(22) Filed: Sep. 24, 2013

(51) Int. Cl. G11C 16/26

(52) U.S. Cl. CPC G11C 16/26
USPC 365/185.03; 365/185.21

(57) ABSTRACT

A data storage device includes a controller that is configured to determine a first read voltage for a first page of a non-volatile memory (e.g., a lower page of a Multi-Level Cell flash memory device). The controller is also configured to determine a second read voltage for a second page (e.g., an upper page) of the non-volatile memory by applying an offset value to the first read voltage. The controller is also configured to store data identifying the first read voltage and the second read voltage.

### FIELD OF THE DISCLOSURE

The present disclosure is generally related to determining read voltages for a non-volatile memory.

### BACKGROUND

Non-volatile data storage devices, such as embedded flash memories, universal serial bus (USB) flash memory devices, or removable storage cards, have allowed for increased portability of data and software applications. Flash memory devices can enhance data storage density by storing multiple bits in each flash memory cell. For example, Multi-Level Cell (MLC) flash memory devices can provide increased storage density by storing 3 bits per cell, 4 bits per cell, or more.

Storing multiple bits of information in a single flash memory cell typically includes mapping sequences of bits to states of the flash memory cell. For example, a first sequence of bits “110” may correspond to a first state of a flash memory cell and a second sequence of bits “010” may correspond to a second state of the flash memory cell. After determining that a sequence of bits is to be stored into a particular flash memory cell, the particular flash memory cell may be programmed to a state (e.g., by setting a threshold voltage) that corresponds to the sequence of bits.

Once memory cells in a data storage device have been programmed, data may be read from the memory cells by sensing the programmed state of each memory cell by comparing the cell threshold voltage to one or more read voltages. However, the sensed programming states can sometimes vary from the written programmed states due to one or more factors, such as data retention and program disturb conditions.

### SUMMARY

Accuracy of reading data stored in a data storage device may be improved by updating a set of read voltages used to read the stored data in order to reduce an estimated or actual bit error rate associated with reading the stored data. Updating the set of read voltages by selecting an optimal read voltage associated with each page can be resource intensive. Accordingly, a simplified process that utilizes less time and power can be used to update the set of read voltages according to a particular embodiment. For example, a first read voltage for a first page of the non-volatile memory may be determined (e.g., by performing a plurality of read operations using different test read voltages to read values representative of a codeword from the first page and selecting the first read voltage based on results of the plurality of read operations). A second read voltage may be determined by applying an offset value to the first read voltage. Thus, both the first and second read voltages can be updated based on the plurality of read operations for the first page. Additional read voltages may also be determined by applying other offset values to the first read voltage. The offset value or offset values may be predetermined values or may be selected (e.g., from a lookup table) or otherwise determined based on information related to the non-volatile memory, such as a count of read cycles associated with the non-volatile memory (e.g., read cycles of a particular storage element of the non-volatile memory), a count of write cycles associated with the non-volatile memory (e.g., write cycles of a particular storage element of the non-volatile memory), or both.

### BRIEF DESCRIPTION OF THE DRAWINGS

FIG. 1 is a block diagram of a particular illustrative embodiment of a system including a data storage device configured to generate updated read voltages;

FIG. 2 is a diagram illustrating a particular embodiment of a method of updating read voltages that may be performed by the data storage device of FIG. 1;

FIG. 3 is a diagram illustrating another particular embodiment of a method of updating read voltages that may be performed by the data storage device of FIG. 1;

FIG. 4 is a flow chart of a particular embodiment of a method of updating read voltages that may be performed by the data storage device of FIG. 1;

FIG. 5 is a flow chart of another particular embodiment of a method of updating read voltages that may be performed by the data storage device of FIG. 1;

FIG. 6 is a flow chart of particular embodiment of a method of selecting a first read voltage that may be performed by the data storage device of FIG. 1;

FIG. 7 is a flow chart of another particular embodiment of a method of selecting a first read voltage that may be performed by the data storage device of FIG. 1;

FIG. 8 is a flow chart of another particular embodiment of a method of selecting a first read voltage that may be performed by the data storage device of FIG. 1;

FIG. 9 is a flow chart of another particular embodiment of a method of updating read voltages that may be performed by the data storage device of FIG. 1; and

FIG. 10 is a flow chart of another particular embodiment of a method of updating read voltages that may be performed by the data storage device of FIG. 1.

### DETAILED DESCRIPTION

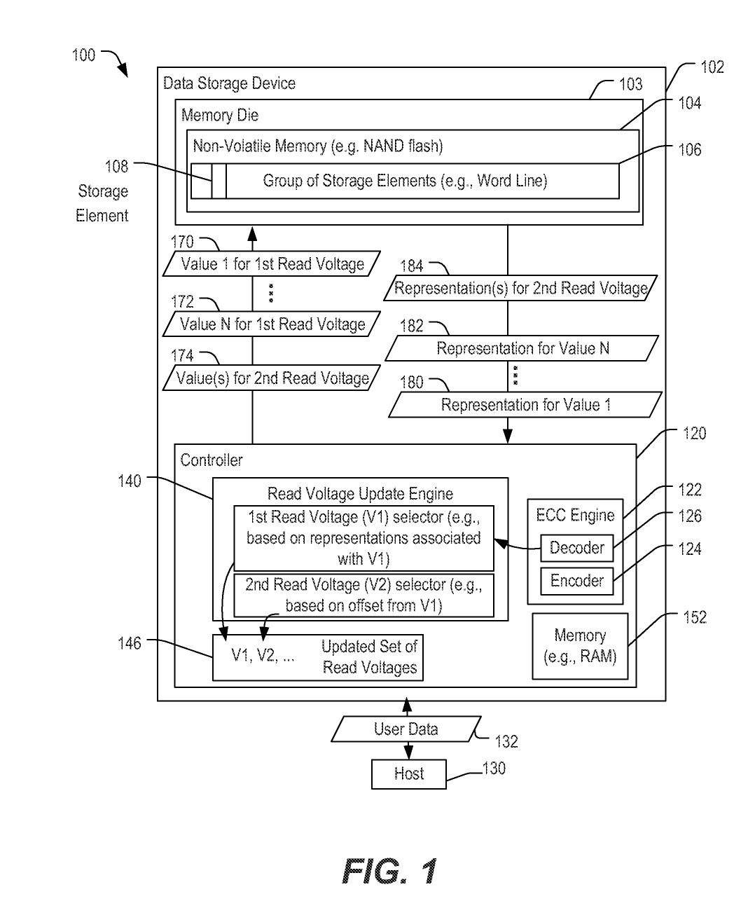

Referring to FIG. 1, a particular embodiment of a system 100 includes a data storage device 102 coupled to an accessing device, such as a host device 130. The data storage device 102 is configured to generate an updated set of read voltages 146, as described further below.

The host device 130 may be configured to provide data, such as user data 132, to be stored at a non-volatile memory 104 or to request data to be read from the non-volatile memory 104. For example, the host device 130 may include a mobile telephone, a music player, a video player, a gaming console, an electronic book reader, a personal digital assistant (PDA), a computer, such as a laptop computer, notebook computer, or tablet, any other electronic device, or any combination thereof. The host device 130 communicates via a memory interface that enables reading from the non-volatile memory 104 and writing to the non-volatile memory 104. For example, the host device 130 may operate in compliance with a Joint Electron Devices Engineering Council (JEDEC) industry specification, such as a Universal Flash Storage (UFS) Host Controller Interface specification or a JEDEC embedded MultiMedia Card (eMMC) device specification. As other examples, the host device 130 may operate in compliance with one or more other specifications, such as a Secure Digital (SD) Host Controller specification as an illustrative example. The host device 130 may communicate with the non-volatile memory 104 in accordance with any other suitable communication protocol.

The data storage device 102 includes the non-volatile memory 104 coupled to a controller 120. For example, the non-volatile memory 104 may be a NAND flash memory. The non-volatile memory 104 includes a representative group 106 of storage elements, such as a word line of a multi-level cell (MLC) flash memory. The group 106 includes a representative storage element 108, such as a flash MLC cell. For example, the data storage device 102 may be configured to be coupled to the host device 130 as embedded memory, such as eMMC® (trademark of JEDEC Solid State Technology Association, Arlington, Va.) and eSD, as illustrative examples. To illustrate, the data storage device 102 may correspond to an eMMC (embedded MultiMedia Card) device. As another example, the data storage device 102 may be a memory card, such as a Secure Digital SD® card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof.

The controller 120 is configured to receive data and instructions from and to send data to the host device 130. The controller 120 is further configured to send data and commands to the non-volatile memory 104 and to receive data from the non-volatile memory 104. For example, the controller 120 is configured to send data and a write command to instruct the non-volatile memory 104 to store the data to a specified address. As another example, the controller 120 is configured to send a read command to the non-volatile memory 104.

The controller 120 includes an ECC engine 122 that is configured to receive data to be stored to the non-volatile memory 104 and to generate a codeword. For example, the ECC engine 122 may include an encoder 124 configured to encode data using an ECC encoding scheme, such as a Reed Solomon encoder, a Bose-Chaudhuri-Hocquenghem (BCH) encoder, a low-density parity check (LDPC) encoder, a Turbo Code encoder, an encoder configured to encode one or more other ECC encoding schemes, or any combination thereof. The ECC engine 122 may include a decoder 126 configured to decode data read from the non-volatile memory 104 to detect and correct, up to an error correction capability of the ECC scheme, any bit errors that may be present in the data.

The controller 120 includes a read voltage update engine 140 that is configured to generate the updated set of read voltages 146 by determining a first read voltage for a first page of the non-volatile memory 104 and determining a second read voltage for a second page of the non-volatile memory 104 by applying an offset value to the first read voltage. In some embodiments, the first page is a logical lower page of the non-volatile memory 104 because reading the logical lower page uses less sensing time. However, in other embodiments, the first page may be a logical middle page or a logical upper page of the non-volatile memory 104. The first read voltage may be determined using a search process. For example, the first read voltage may be determined by performing a plurality of read operations to read values representative of at least one codeword from the first page. Two or more of the plurality of read operations are performed using different test read voltages. The first read voltage may be selected based on the results of the plurality of read operations. For example, a decode operation may be performed based on results of each of the plurality of read operations, and a particular read voltage that generated fewest errors may be selected as the first read voltage. As another example, the results of the plurality of read operations may be used to estimate a location of a boundary between the first page and an adjacent page (e.g., the second page or a third page). In this example, the first read voltage may be selected based on the boundary between the first page and the adjacent page. As yet another example, a decode operation may be performed based on the results of each of the plurality of read operations and a first particular read voltage that has few enough errors to be successfully decoded is selected as the first read voltage.

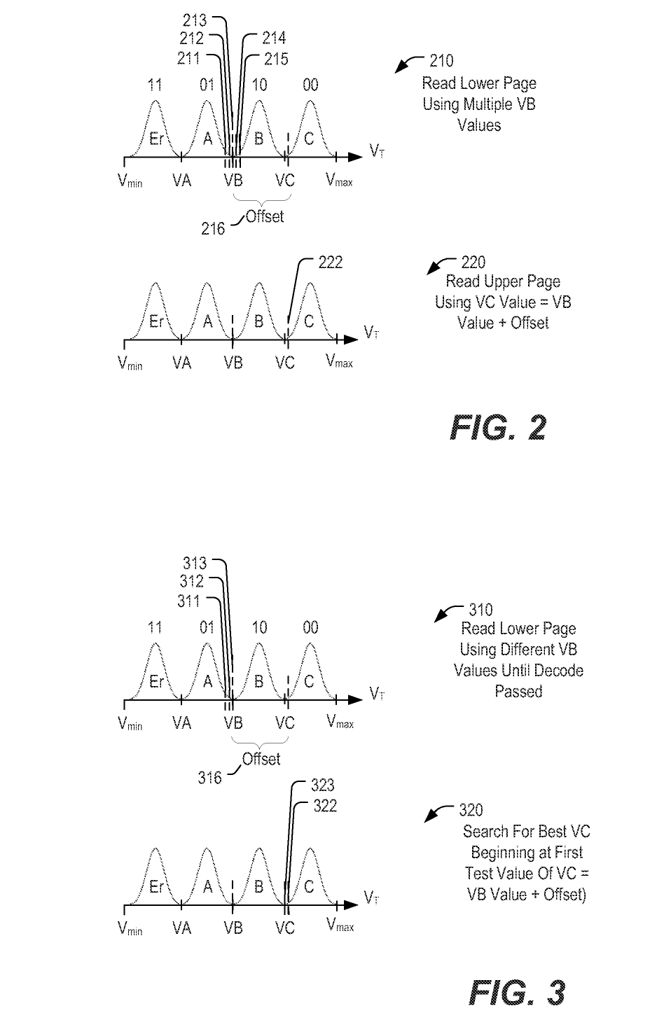

To illustrate, referring to FIG. 2, a first graph 210 and a second graph 220 show histograms or distributions of storage element threshold values having clusters representing states Erase (Er), A, B, and C, in a 2-bit per cell (2BPC) multi-level cell (MLC) implementation. A set of read voltages VA, VB, and VC define boundaries between the states and may be used to determine a state of a storage element. For example, applying the read voltage VA to a word line of the group 106 activates storage elements having threshold voltages less than VA while storage elements having threshold voltages greater than VA are not activated. Although the graphs 210 and 220 illustrate a two bits per storage element (2BPC) MLC, in other implementations the non-volatile memory 104 may store more than two bits per storage element. For example, in a three bit per storage element (3BPC) MLC implementation, eight states may be represented.

Some storage elements originally set to the Er state may experience a threshold voltage shift that causes the threshold voltages of the storage elements to be greater than VA. Reading these storage elements using VA results in bit errors because the storage elements are read as having a “01” value (corresponding to state A) rather than having a “11” value (corresponding to the Er state). Similarly, some storage elements originally programmed to state A may experience a threshold voltage shift that causes the threshold voltages of the storage elements to be less than VA. Reading these storage elements using VA also results in bit errors because the storage elements are read as having a “11” value rather than having a “01” value. Similar shifts may occur at boundaries between other states.

The read voltage update engine 140 of FIG. 1 may be configured to adjust VB, such as by sequentially assigning a first test value 211, a second test value 212, a third test value 213, a fourth test value 214, and a fifth test value 215, without adjusting the other read voltages VA and VC. Each resulting set of read voltages may be used to read the data from the group 106, and the resulting data may be processed to select a value (e.g., the first read value) of VB. For example, the resulting data may correspond to a codeword, which may be decoded by the decoder 126. ECC related information from the decoder 126 may be used to select one of the test values 211-215 that results in a lowest estimated or actual number of bit errors in the data (as compared to the estimated or actual number of bit errors corresponding to the other test values 211-215). More generally, the ECC related information may be used to select one of the test values that results in a minimal (or maximal) detected value of an ECC related metric corresponding to the ECC related information. For example, an objective may be to determine a read threshold value of VB that minimizes the bit error rate. As another example, an objective may be to minimize ECC power, latency, throughput, or any other ECC related metric. Also, it is not necessary to decode the codewords to determine an “optimal” read voltage. Other ECC related information may be used without fully decoding (e.g. computing the number of unsatisfied ECC parity-check equations, also known as syndrome weight, without full decoding, or BER estimation without decoding, as non-limiting examples).

After selecting a first read voltage, corresponding to a value of VB, the read voltage update engine 140 may determine a second read voltage 222 corresponding to a second page by applying an offset value 216 to the first read voltage (as illustrated in the second graph 220 of FIG. 2). In a particular embodiment, the offset value 216 is a fixed, predetermined value (e.g., a constant) determined based on testing of a plurality of memory devices, such as memory devices of a type embodied in a memory die 103, to determine a fixed offset value that most accurately models a page boundary over time. For example, testing has shown that for some memory die the boundary between states B and C (e.g., VC) tends to shift by approximately the same amount and in the same direction as the boundary between states A and B (e.g., VB). Thus, for these memory die, the second read voltage 222 may be approximated by determining the first read voltage, corresponding to VB, and adding a predetermined fixed offset value (e.g., the offset 216).

For some memory die, the relationship between VB and VC may vary over time, for example, as a result of a number of read and/or write cycles that the memory has been subjected to. For such memory die, the offset 216 may be determined dynamically or based on a lookup table. For example, the offset 216 may be determined based on a count of read cycles associated with the non-volatile memory, based on a count of write cycles associated with the non-volatile memory, or based on both the count of read cycles and the count of write cycles. The offset 216 may be calculated based on one or more of the counts (e.g., by the controller 120) or may be read from a lookup table (e.g., stored in the memory 152) based on one or more of the counts.

In another particular embodiment, as illustrated in a first graph 310 and a second graph 320 of FIG. 3, the first read voltage may correspond to a first test read voltage of a set of test read voltages 311-313 that passes a decode operation. That is, no attempt may be made to identify an optimum first read voltage. Rather, a particular test read voltage that generates few enough errors to allow the ECC engine 122 to decode a codeword read using the particular test read voltage is selected as the first read voltage. Although the graphs 310 and 320 illustrate a two bits per storage element (2BPC) MLC, in other implementations the non-volatile memory 104 may store more than two bits per storage element. For example, in a three bit per storage element (3BPC) MLC implementation, eight states may be represented.

In FIG. 3, the first read voltage may be determined by performing a first decode operation using a first set of values representative of a codeword generated by a first read operation using a first test read voltage 311. A determination may be made (e.g., by the controller 120 of FIG. 1) whether the first decode operation is successful based on a number of errors that are correctable by the ECC engine 122. If the first decode operation is successful, the first test read voltage 311 is selected for use as the first read voltage and read operations based on the other test read voltages 312 and 313 are not performed. If the first decode operation is not successful, a second read operation is performed using a second test read voltage 312, and a second decode operation is performed based on results of the second read operation. A determination is made (e.g., by the controller 120 of FIG. 1) whether the second decode operation is successful based on a number of errors that are correctable by the ECC engine 122. If the second decode operation is successful, the second test read voltage 312 is selected for use as the first read voltage and no read operation based on a third test read voltage 313 is performed. If the second decode operation is not successful, a third read operation is performed using the third test read voltage 313, and a third decode operation is performed based on results of the third read operation. A determination is made (e.g., by the controller 120 of FIG. 1) whether the third decode operation is successful based on a number of errors that are correctable by the ECC engine 122. If the third decode operation is successful, the third test read voltage 313 is selected for use as the first read voltage. If the third decode operation is not successful, additional read operations and decode operations are performed using other test read voltages (not shown) until a decode operation is successful, and a particular test read voltage corresponding to the successful decode operation is selected for use as the first read voltage.

In this embodiment, an offset 316 may be applied to the first read voltage to determine an initial test read voltage associated with the second page (e.g., associated with a boundary between B and C). A search may be performed using the initial test read voltage as a starting point or a center point to identify the second read voltage. For example, the search may attempt to identify an optimal or near-optimal value for the second read voltage. The second read voltage may be determined based on a plurality read operations. For example, the plurality of read operations may be used to estimate a boundary, corresponding to VC, of the second page. In another example, the plurality of read operations may be used to identify a particular read voltage that is associated with a successful decode operation. To illustrated, a first read operation may be performed to read first values representative of at least one codeword from the second page of the non-volatile memory using a first test read voltage 323. The first test read voltage 323 may correspond to the first read voltage plus the offset 316. A first decode operation may be performed using the first values representative of the at least one codeword. The controller 120 may determine whether the first decode operation was successful based on a number of errors that are correctable by the first decode operation. When the first decode operation was successful, the first test read voltage 323 may be used as the second read voltage. When the first decode operation is not successful, one or more additional read operations may be performed to read values representative of the at least one codeword from the second page. Each of the one or more additional read operations may use a different test read voltage. Further, one or more additional decode operations may be performed. Each of the one or more additional decode operations uses a set of values representative of the at least one codeword generated by a corresponding read operation of the one or more of read operations. A particular test read voltage (e.g., a second test read voltage 322) that corresponds to a successful decode operation is used as the second read voltage.

During operation of the system 100 of FIG. 1, a determination may be made (e.g., by the controller 120) to perform a read voltage update. The determination to perform the read voltage update may be based on a total number of write/erase (W/E) cycles at the non-volatile memory 104 exceeding a W/E threshold, the time that has elapsed since a block including the group of storage elements 106 has been programmed (or any other indication or metric that is correlated to the time) exceeding a threshold, a number of read operations in a block that includes the group 106 exceeding a read threshold, or an average number of errors detected by the decoder 126 exceeding an error threshold, as illustrative, non-limiting examples.

The controller 120 may also determine whether to update the read voltages using a full cell voltage distribution (CVD) analysis process or a quick cell voltage distribution (QCVD) analysis process. The QCVD analysis process may correspond to one of the processes described with reference to FIGS. 1-3. For example, the QCVD analysis process may include determining a first read voltage value for a first page and determining a second read voltage value for a second page by applying an offset value to the first read voltage. The full CVD analysis process may involve searching for optimal or otherwise desirable read voltage values associated with each boundary. For example, referring to FIG. 2, multiple read operations may be performed at each state boundary (e.g., at Er-A, A-B, and at B-C) to attempt to identify values for VA, VB and VC. As this example illustrates, the full CVD analysis process uses more read operations than the QCVD analysis process, and may use correspondingly more decode operations. Thus, the full CVD analysis process may be more time and resource intensive. Accordingly, the controller 120 may use the full CVD analysis process when the data storage device 102 is not busy or when the QCVD analysis process is not able to generate an updated set of read voltages that is satisfactory. For example, after performing the QCVD analysis process, the controller 120 may determine whether the updated set of read voltages 146 determined by the QCVD analysis process is satisfactory based on whether data read from the non-volatile memory 104 is decodable by the ECC engine 122. If the updated set of read voltages 146 determined by the QCVD analysis process is not satisfactory (e.g., if data read using the updated set of read voltages 146 includes too many errors for the ECC engine 122 to correct), the controller 120 may implement the full CVD analysis process to generate another updated set of read voltages.

To perform the QCVD analysis process, the read voltage update engine 140 may select a first value 170 of the first read voltage as a test read value. The group 106 may store data in a page-by-page, non-interleaved manner, such that a first ECC codeword is stored in a first logical page of a physical page of the group 106 (e.g., a ‘lower’ page corresponding to the least significant bit stored in each storage element of the physical page). A second ECC codeword may be stored in a second logical page of the physical page (e.g., an ‘upper’ page corresponding to the most significant bit stored in each storage element of the physical page). Although not shown in FIGS. 1-3, in some embodiments, the group 106 may include more than two logical pages. For example, a third ECC codeword may be stored in a third logical page of the physical page (e.g., a ‘middle’ page corresponding to the middle bit stored in each storage element of the physical page). When the group includes three or more pages, read voltages associated with the third page and any additional page may be determined by applying an offset from the first read voltage, by applying an offset from the second read voltage, or by searching for a third read voltage corresponding to the third page using multiple read operations.

The controller 120 may provide the first test read voltage at the first value 170 to the non-volatile memory 104 to read a codeword associated with the first page (e.g., the lower page). The first value 170 may correspond to the first test read voltage 211 of the first graph 210 of FIG. 2, may correspond to the first test value 311 of FIG. 3, or both. A first representation 180 of data may be read from the group 106 using the first read voltage at the first value 170 and received at the controller 120. The first representation 180 may be provided to the decoder 126.

The read voltage update engine 140 may select one or more additional values of test read voltages and perform corresponding read operations. For example, an Nth value 172 of the first read voltage may be used to perform a read operation. The Nth value 172 of the first read voltage may correspond to the second test value 212 of FIG. 2, may correspond to the second test value 312 of FIG. 3, or both. The first read voltage at the Nth value 172 may be provided to the non-volatile memory 104 and used to read a corresponding representation 182 that is provided to the decoder 126.

The decoder 126 may generate ECC related information responsive to each of the representations 180-182. Alternatively, the ECC related information may be generated by a separate designated ECC related function (e.g., a separate hardware engine) rather than by the decoder 126. The read voltage update engine 140 may receive or otherwise access the ECC related information to determine or estimate a number of errors or a bit error rate (BER) for each of the representations 180-182. Alternatively, or in addition, the read voltage update engine 140 may determine any other ECC related metric.

To illustrate, when the decoder 126 fully decodes each of the representations 180-182, the decoder 126 may generate information indicating a number of corrected errors. The read voltage update engine 140 may compare the number of corrected errors resulting from reading the data with each of the values 170-172 to select the particular value 170-172 having the lowest identified number of corrected errors among the values 170-172. The selected value may be used as an updated value of the first read voltage.

In other implementations, latency associated with fully decoding each of the representations 180-182 may be avoided by estimating a bit error rate (BER) or number of errors without fully decoding the representations 180-182. For example, the decoder 126 may generate a syndrome value indicating a number of parity check equations that are unsatisfied for each of the representations 180-182. The syndrome value for each of the representations 180-182 generally indicates a relative amount of errors in each of the corresponding representations 180-182. The syndrome value may be generated using dedicated hardware circuitry with reduced latency as compared to full decoding. The ECC related information may include syndrome values for each of the representations 180-182 and the read voltage update engine 140 may search and/or sort the syndrome values to identify a lowest estimated BER of the representations 180-182 and to select a corresponding value as the updated first read voltage.

As another example, a length of time corresponding to a decoding operation may be used to estimate a number of errors or BER. To illustrate, representations of data having a greater number of errors may generally require longer decoding (e.g., more iterations for convergence, longer error location search processing, etc.) than representations of data having fewer errors. The decoder 126 may be configured to fully decode a first representation of data (e.g., the representation 180) and to store the decoding time for the first representation. For each subsequent representation of data (e.g., the representation 182), the decoder 126 may terminate decoding if the decoding time exceeds the stored decoding time, or may update the stored decoding time if the decoding time is less than the stored decoding time. The ECC related information may indicate one or more decoding times or relative decoding times of the representations 180-182 to enable the read voltage update engine 140 to identify a shortest of the decoding times of the representations 180-182 and to select a corresponding value as the first read voltage.

As another example, a number of bit values that change during a decoding operation may be used to estimate a number of errors or BER. To illustrate, during an iterative decoding process, representations of data having a greater number of errors may experience more “bit flips” prior to convergence than representations of data having a lesser number of errors. The decoder 126 may be configured to track a number of bit flips for each representation 180-182 and to indicate resulting counts of bit flips in the ECC related information to enable the read voltage update engine 140 to identify a lowest count of bit flips of the representations 180-182 and to select a corresponding value as the first read voltage.

As another example, at least a portion of the data stored in the group 106 may be reference data. The portion of each of the representations 180-182 that corresponds to the reference data may be compared to the reference data to identify errors. For example, the decoder 126 may include circuitry configured to compare a portion of each representation 180-182 to the reference data and to generate a count of detected bit errors. The resulting counts may be provided in the ECC related information to enable the read voltage update engine 140 to identify a lowest of the counts of reference data errors of the representations 180-182 and to select a corresponding value as the first read voltage.

As yet another example, the values 170-172 may be provided to the non-volatile memory 104 sequentially. The decoder 126 may decode each representation 180-182 as it is received. The decoder 126 may provide an indication, via the ECC related information, when one of the representations 180-182 is able to be fully decoded (e.g., has few enough errors that the decoder 126 is able to correct the errors). In this example, the read voltage update engine 140 may select a value corresponding to a decodable representation as the first read voltage.

After selection of the first read voltage, the read voltage update engine 140 may store data indicating the first read voltage in the updated set of read voltages 146. The read voltage update engine 140 may determine a second read voltage (corresponding to a second page of the non-volatile memory 104) by applying an offset to the first read voltage. The value of the offset may be predetermined and fixed (e.g., constant). Alternatively, the value of the offset may be determined based on information related to the non-volatile memory 104, such as a count of read and/or write cycles. In this example, the read voltage update engine 140 may access the a portion of the non-volatile memory 104 or the memory 152 to determine the count of read and/or write cycles and to read a corresponding value of the offset from a lookup table in the memory 152 or in the non-volatile memory 104. Alternatively, the read voltage update engine 140 may access a portion of the non-volatile memory 104 or the memory 152 to determine the count of read and/or write cycles and may calculate the offset based on the count. The read voltage update engine 140 may store data indicating the second read voltage in the updated set of read voltages 146

In a particular embodiment, the read voltage update engine 140 may use the first test read value and the offset to select a set of voltages to be searched to determine the second read voltage. For example, after determining the first read voltage, the read voltage update engine 140 may provide one or more test values 174 for the second read voltage to the non-volatile memory 104. One or more representations 184 (e.g., a representation corresponding to each of the test values 174) may be provided to the decoder 126. The second read voltage may be selected based on the one or more representations 184. For example, the second read voltage may be selected based on ECC related information using a selection process similar to one of the selection processes described above for the first read voltage. To illustrate, the second read voltage may be selected based on a bit error rate associated with each of the one or more representations 184, based on a number of corrected errors associated with each of the one or more representations 184, based on a syndrome value associated with each of the one or more representations 184, based on a decoding time associated with each of the one or more representations 184, based on a count of bit flips associated with each of the one or more representations 184, based on a count of detected bit errors associated with each of the one or more representations 184, or based on which of the one or more representations 184 is decodable.

By applying an offset to the first read voltage to determine the second read voltage, estimates of the first and second read voltages can be determined in a faster and less resource intensive manner than by using a full CVD analysis process. For example, a full CVD analysis process may use thirty-two (32) or more reads of two pages, resulting in latency of about 4 ms, to find “optimal” read voltages for the three boundaries illustrated in FIGS. 2 and 3. However, in a particular embodiment (as described with reference to FIG. 2), a QCVD analysis process may use only 5 reads of a single page (e.g., a lower page) to determine estimates of read voltages for the lower page and the upper page. Thus, the QCVD analysis process results in latency of less than 0.6 ms. Additionally, in a particular embodiment, to determine the first read voltage, the QCVD analysis process may read a single codeword (e.g., 4 KB) rather than reading an entire page. The single codeword is sufficient to enable processing by the decoder 126 to select a value of the first read voltage. Thus, when the second read voltage is determined by applying the offset value, considerable sensing time can be saved relative to the full CVD analysis process. For example, in the embodiment of FIG. 2, the second read voltage determined by applying the offset value to the first read voltage can be used to generate the updated set of read voltages 146 without performing a read operation using the second read voltage (e.g., a verification read operation before storing the updated set of read voltages 146). Alternately, as in the embodiment of FIG. 3, the second page (e.g., the upper page) can be read using the second read voltage determined by applying the offset value to verify that the second read voltage is useable. If it turns out that the second read voltage is not useable (e.g., the second read voltage results in uncorrectable errors), the full CVD analysis process may be implemented.

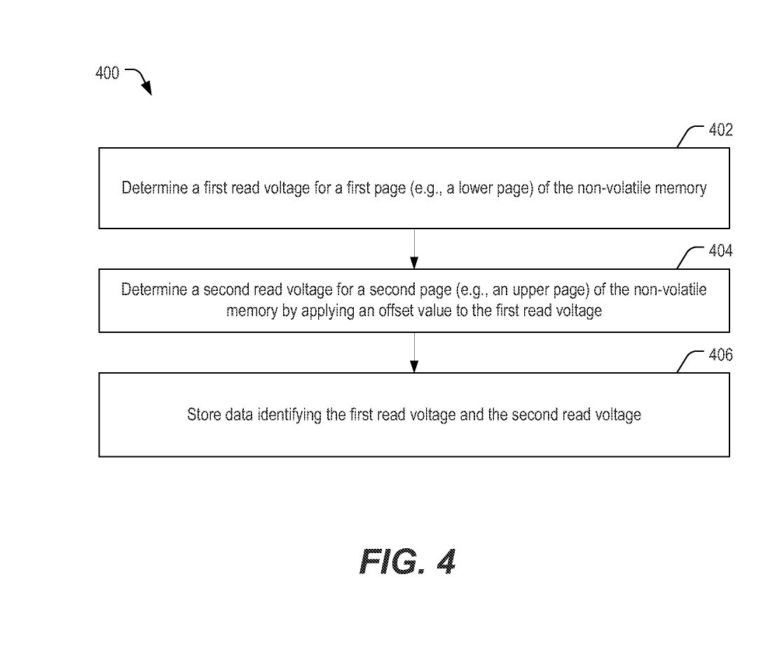

FIG. 4 depicts an embodiment of a method 400 of updating a set of read voltages. The method 400 may be performed in a data storage device including a controller and a non-volatile memory, such as the data storage device 102 of FIG. 1. The method 400 illustrates a simplified embodiment of a quick cell voltage distribution (QCVD) analysis process.

The method 400 includes determining a first read voltage for a first page of the non-volatile memory, at 402. For example, the first read voltage may be determined by using different test values 211-215 of the read voltage VB to generate a representation of a codeword from the first page. The first read voltage may correspond to a test value that generates a representation that is decodable by the decoder 126 based on a number of errors correctable by the decoder 126. Alternately, the representations of the codeword may be used to select an optimal or near-optimal value of the first read voltage (e.g., by estimating a location of a boundary between the A state and the B state in FIG. 2).

The method 400 may also include determining a second read voltage for a second page of the non-volatile memory by applying an offset value to the first read voltage, at 404. The offset value may be a predetermined fixed value or a value that depends on information related to the non-volatile memory. For example, the offset value may be selected from a lookup table or may be calculated. The method may also include storing data identifying the first read voltage and the second read voltage, at 406. For example, the controller 120 may store the updated set of read voltages 146. The updated set of read voltages 146 may be used during a subsequent memory operations (e.g., read operations or write operations).

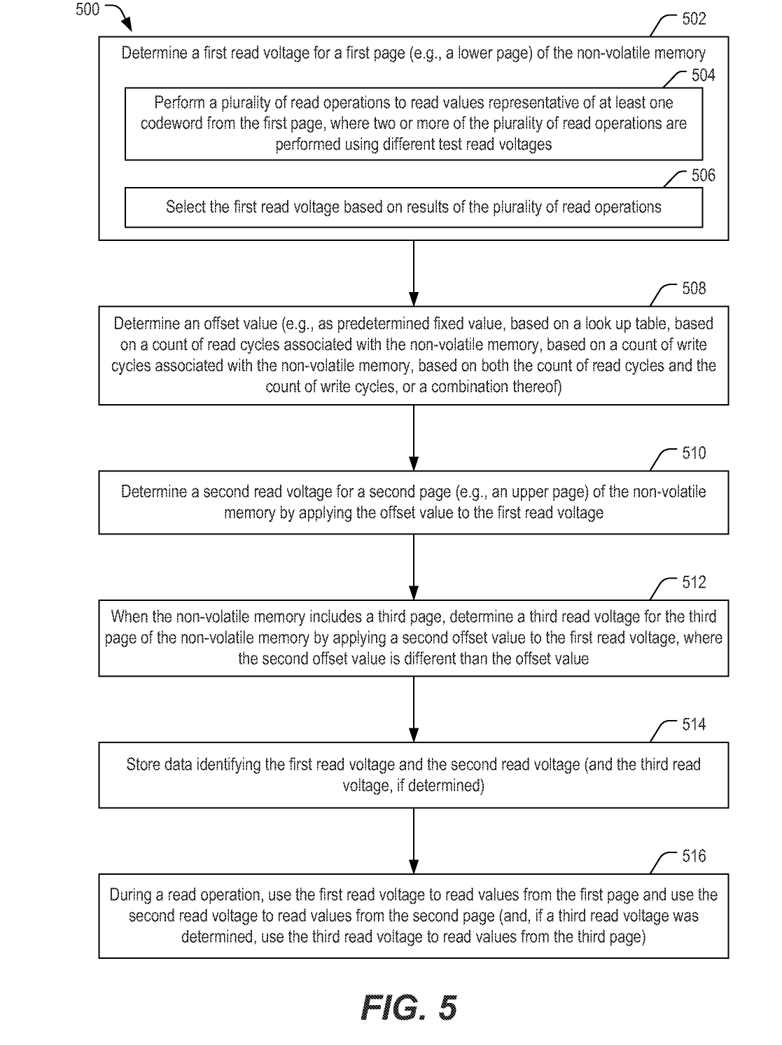

FIG. 5 depicts another embodiment of a method 500 of updating a set of read voltages. The method 500 may be performed in a data storage device including a controller and a non-volatile memory, such as the data storage device 102 of FIG. 1. The method 500 illustrates another quick cell voltage distribution (QCVD) analysis process.

The method 500 includes determining a first read voltage for a first page (e.g., a lower page) of the non-volatile memory, at 502. Determining the first read voltage for the first page may include, at 504, performing a plurality of read operations to read values representative of at least one codeword from the first page. Two or more of the plurality of read operations are performed using different test read voltages. For example, as illustrated in the first graph 210 of FIG. 2, five test read voltages 211-215 may be used to read values representative of a codeword from the first page of a Multi-Level Cell (MLC) flash memory device.

Determining the first read voltage for the first page may also include, at 506, selecting the first read voltage based on results of the plurality of read operations. For example, a particular test read voltage of the test read voltages 211-215 may be selected as the first read voltage based on a bit error rate, a number of corrected errors, a syndrome value, a decoding time, a count of bit flips, a count of detected bit errors, whether a representation is decodable, other ECC related information, or a combination thereof.

The method 500 may also include determining an offset value, at 508. In a particular embodiment, the offset value is a fixed value that is based on a known or expected relationship between the first read voltage and the second read voltage. In another particular embodiment, the offset value is determined based on information associated with the non-volatile memory, such as a count of read cycles associated with the non-volatile memory, a count of write cycles associated with the non-volatile memory, or both the count of read cycles and the count of write cycles. The offset value may be calculated or may be determined based on a lookup table.

The method 500 may include determining a second read voltage for a second page (e.g., an upper page) of the non-volatile memory by applying the offset value to the first read voltage, at 510. When the non-volatile memory includes a third page (e.g., a middle page), the method 500 may include determining a third read voltage for a third page of the non-volatile memory by applying a second offset value to the first read voltage, at 512. For example, when the non-volatile memory is a 3-bit per cell (3BPC) multi-level cell (MLC) memory device, the third read voltage may be determined. The second offset value may be different than the offset value used to determine the second read voltage. The second offset value may be a predetermined fixed value that is based on a known or expected relationship between the first read voltage and the third read voltage. In another particular embodiment, the second offset value is determined based on information associated with the non-volatile memory, such as a count of read cycles associated with the non-volatile memory, a count of write cycles associated with the non-volatile memory, or both the count of read cycles and the count of write cycles. The offset value may be calculated or may be determined based on a lookup table.

The method 500 may also include storing data identifying the first read voltage and the second read voltage, at 514. For example, the data identifying the first read voltage and the second read voltage may be stored by the controller 120 as the updated set of read voltages 146. If a third read voltage has been determined, the method 500 may also store data identifying the third read voltage.

The method 500 also includes, at 516, during a read operation, using the first read voltage to read values from the first page and using the second read voltage to read values from the second page. If a third read voltage has been determined for a third page, the method 500 may also include using the third read voltage to read values from the third page.

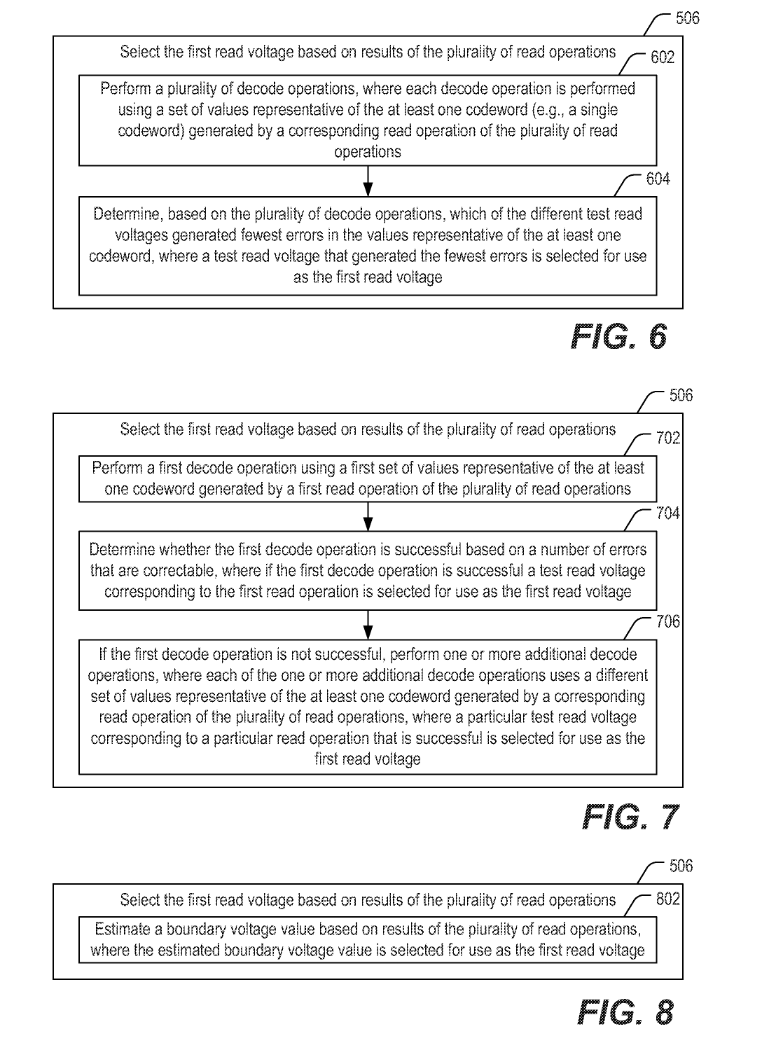

FIGS. 6-8 depicts flowcharts of embodiments of methods of selecting the first read voltage based on results of a plurality of read operations, corresponding to box 506 of the method 500. In FIG. 6, selecting the first read voltage based on results of a plurality of read operations includes, at 602, performing a plurality of decode operations. Each of the plurality of decode operations is performed using a set of values representative of at least one codeword generated by a corresponding read operation of the plurality of read operations. For example, a first decode operation is performed using values representative of the at least one codeword (e.g., the representation 180 of FIG. 1) generated by a first read operation using a first test read voltage (e.g., the first value 170 of FIG. 1), and a second decode operation is performed using values representative of the at least one codeword (e.g., the representation 182 of FIG. 1) generated by a second read operation using a second test read voltage (e.g., the Nth value 172 of FIG. 1). At 604, a determination is made, based on the plurality of decode operations, as to which of the different test read voltages generated fewest errors in the values representative of the at least one codeword. A test read voltage that generated the fewest errors is selected for use as the first read voltage.

In FIG. 7, selecting the first read voltage based on results of a plurality of read operations includes, at 702, performing a first decode operation using a first set of values representative of the at least one codeword (e.g., the representation 180 of FIG. 1) generated by a first read operation of the plurality of read operations. At 704, a determination is made whether the first decode operation was successful based on a number of errors that are correctable. For example, the ECC engine 122 may generate ECC related information indicating whether the representation 180 includes more errors than are correctable by the decoder 126. If the first decode operation was successful, a test read voltage corresponding to the first read operation (e.g., the first value 170 of FIG. 1) is selected for use as the first read voltage. At 706, if the first decode operation is not successful, one or more additional decode operations is performed. Each of the one or more additional decode operations uses a different set of values representative of the at least one codeword generated by a corresponding read operation of the plurality of read operations. A particular test read voltage corresponding to a particular read operation that is successful is selected for use as the first read voltage.

In FIG. 8, selecting the first read voltage based on results of a plurality of read operations includes, at 802, estimating a boundary voltage value based on results of the plurality of read operations. For example, the plurality of read operations may be analyzed to determine a boundary voltage between two states, such as the boundary voltage VB between the A state and the B state of FIGS. 2 and 3. To illustrate, the boundary voltage value may be estimated based on bit error rates of the results of the plurality of read operations, based on a number of corrected errors of the results of each of the plurality of read operations, based on syndrome values of the results of the plurality of read operations, based on decoding times of the results of the plurality of read operations, based on a count of bit flips of the results of each of the plurality of read operations, based on a count of detected bit errors of the results of each of the plurality of read operations, or a combination thereof. The estimated boundary voltage value is selected for use as the first read voltage.

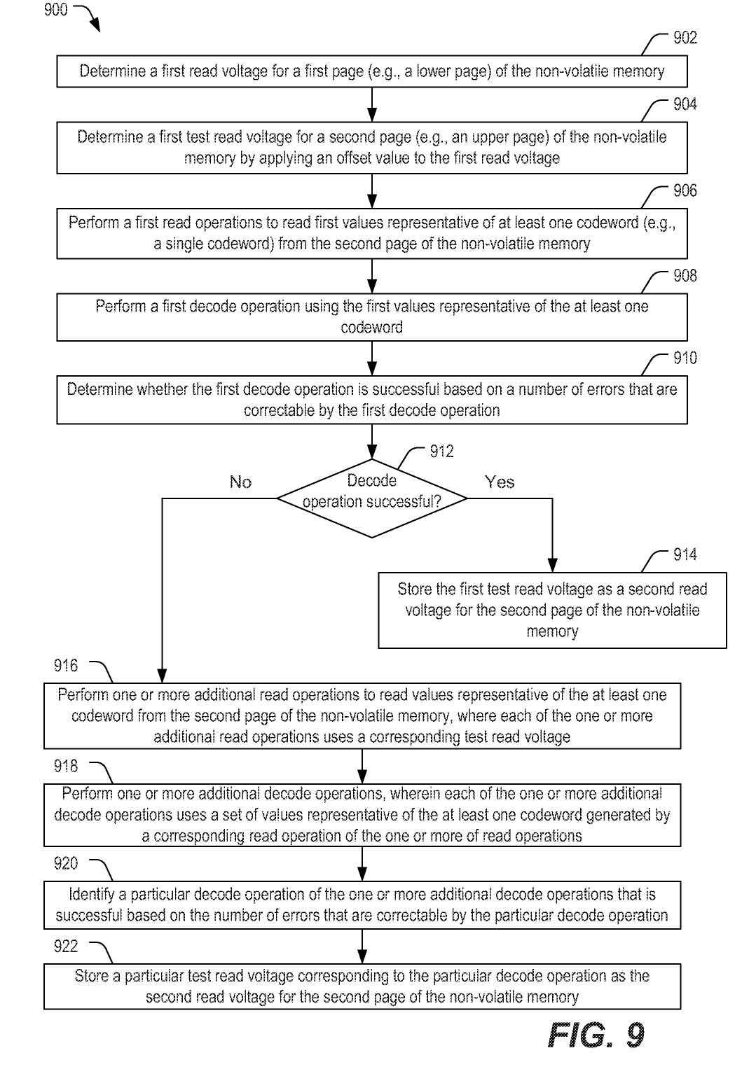

FIG. 9 depicts another embodiment of a method 900 of updating a set of read voltages. The method 900 may be performed in a data storage device including a controller and a non-volatile memory, such as the data storage device 102 of FIG. 1. The method 900 illustrates another quick cell voltage distribution (QCVD) analysis process

The method 900 includes determining a first read voltage for a first page (e.g., a lower page) of the non-volatile memory, at 902. For example, as illustrated in graph 310 of FIG. 3, one or more read operations may be performed using test read voltages 311-313. Each read operation may generate a set of values representative of the at least one codeword, which may be provided to a decoder (such as the decoder 126 of FIG. 1). A particular test read voltage that generates a set of values representative of the at least one codeword that the decoder is able to successfully decode (based on a number of errors correctable by the decoder) may be used as the first read voltage.

The method 900 also includes determining a first test read voltage for a second page (e.g., an upper page) of the non-volatile memory by applying an offset value to the first read voltage. For example, as illustrated in graph 310 of FIG. 3, the first test read voltage 322 corresponds to the first read voltage plus the offset 316. The method 900 also includes performing a first read operation to read first values representative of at least one codeword from the second page of the non-volatile memory, at 906. For example, in FIG. 1, the value(s) 174 of the second read voltage may correspond to test read values, which are used to generate the representation(s) 184.

The method 900 also includes performing a first decode operation using the first values representative of the at least one codeword, at 908. For example, one of the representation(s) 184 may be provided to the decoder 126, which may attempt to decode the representation.

The method 900 also includes determining whether the first decode operation is successful based on a number of errors that are correctable by the first decode operation, at 910. For example, the decoder 126 or the ECC engine 122 may generate ECC related data that indicates a number of errors corrected while decoding the representation or ECC related data that indicates whether decoding of the representation was successful.

When the first decode operation is successful, at 910, the method 900 includes storing the first test read voltage as a second read voltage for the second page of the non-volatile memory, at 914. For example, when the ECC related data indicates that the representation was successfully decoded by the decoder 126, the read voltage update engine 140 may store the updated set of read voltages including a value of the first test read voltage as the second read voltage.

When the first decode operation is not successful, at 912, the method 900 includes performing one or more additional read operations to read values representative of the at least one codeword from the second page of the non-volatile memory, at 916. Each of the one or more additional read operations uses a corresponding test read voltage. For example, when the first test read voltage 322 of FIG. 3 does not generate results (e.g., one of the representations 184) that the decoder 126 is able to decode, the second test read voltage 323 may be used to generate another of the representations 184.

The method 900 also includes performing one or more additional decode operations, at 918. Each of the one or more additional decode operations uses a set of values representative of the at least one codeword (e.g., one of the representations 184) generated by a corresponding read operation of the one or more of read operations. Each of the read operations may use a different test read voltage (e.g., one of the values 174).

The method 900 also includes identifying a particular decode operation of the one or more additional decode operations that is successful based on the number of errors that are correctable by the particular decode operation, at 920, and storing a particular test read voltage corresponding to the particular decode operation as the second read voltage for the second page of the non-volatile memory, at 922. For example, when the decoder 126 or the ECC engine 122 generates ECC related information indicating that one of the representations 184 has been successfully decoded, the read voltage update engine 140 may store a value of the test read voltage that generated the successfully decoded representation in the updated set of voltages 146 as the second read voltage. The updated set of read voltages 146 may be used during a subsequent memory operations (e.g., read operations or write operations).

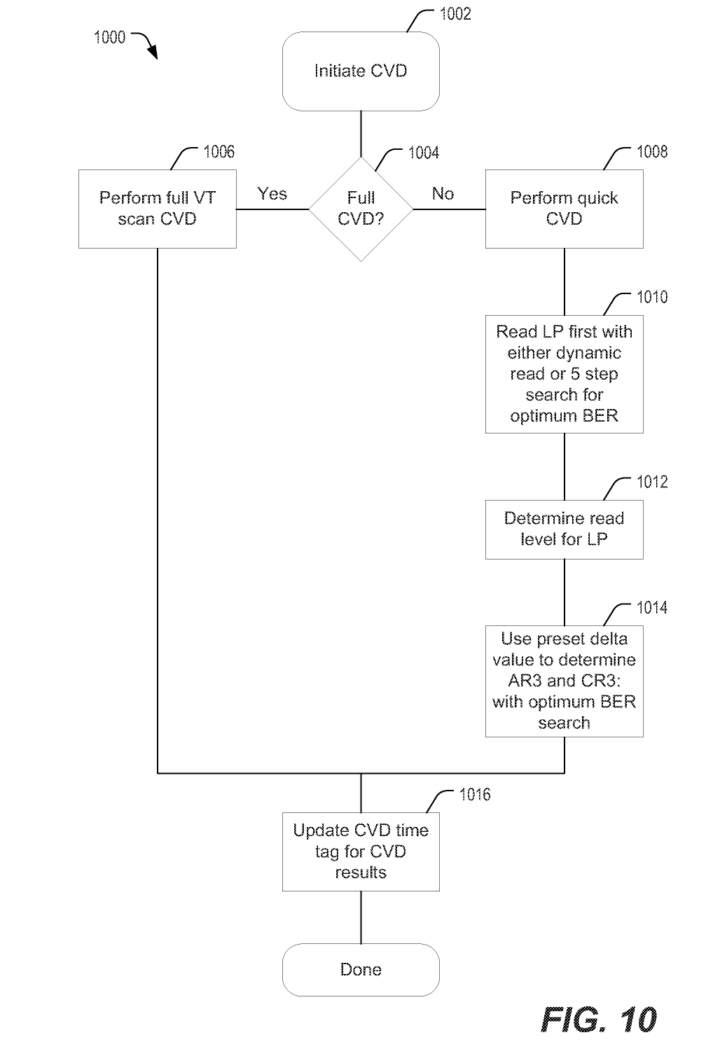

FIG. 10 is a flow chart of another particular embodiment of a method 1000 of updating read voltages that may be performed by the data storage device of FIG. 1. The method 1000 includes, at 1002, initiating a cell voltage distribution (CVD) analysis process. For example, the controller 120 may initiate the CVD analysis process based on ECC related information (e.g., an indication that one or more codewords provided to the decoder 126 were not decodable based on a number of errors decodable by the decoder 126). In another example, the controller 120 may initiate the CVD analysis process based on information related to usage of the data storage device 102, such as a number of read cycles, a number of write cycles, other usage information, or combination thereof.

The method 1000 includes, at 1004, determining whether the CVD analysis process should include a full CVD analysis or a quick CVD (QCVD) analysis. In a particular embodiment, the full CVD analysis may be performed when the data storage device 102 has high resource availability (e.g., when no user data 132 is being read from or written to the non-volatile memory 104), when a particular number of QCVD analysis operations have been performed since a previous full CVD analysis was performed, when a QCVD operation that was most recently performed was not successful (e.g., using read voltages set based on the most recent QCVD results in codewords that are not decodable), based on other factors, or a combination thereof. The QCVD analysis process may be used when available resources of the data storage device 102 are limited (e.g., when user data 132 is being read from or written to the non-volatile memory 104), when fewer than a particular number of QCVD analysis operations have been performed since a previous full CVD analysis was performed, based on other factors, or a combination thereof.

When the full CVD analysis is to be performed, at 1004, a full voltage threshold scan CVD analysis operation may be performed, at 1006. For example, for a 2-bit per cell (2BPC) multi-level cell (MLC) implementation, read operations and corresponding ECC operations (e.g., decode operations) may be performed for thirty-two (32) different read voltages. The read operations and corresponding ECC operations may be used to determine boundary locations between states, such as values of VA, VB and VC between states A, B, and C, respectively of FIGS. 2 and 3.

When the full CVD analysis is not to be performed, at 1004, the QCVD analysis operation may be performed, beginning at 1008. The QCVD analysis operation may include or correspond to any of the methods 400, 500, or 900 of FIGS. 4, 5 and 9, respectively. In the particular embodiment illustrated in FIG. 10, the QCVD analysis operation includes reading a lower page (LP) of a multi-level cell memory device using either dynamic reads or a 5 step test read search to determine an optimum (e.g., least among a set of results) bit error rate, at 1010. The method 1000 also includes determined a read level (e.g., a first read voltage) for the lower page, at 1012. The method 1000 includes using a preset delta value (e.g., an offset value) to determine AR3 (e.g., a read voltage corresponding to VA of FIG. 2), using a second preset delta value (e.g., a second offset value) to determine CR3 (e.g., a read voltage corresponding to VC of FIG. 2), or using preset delta values to determine both AR3 and CR3, at 1014. Additionally, AR3, CR3, or both, may be further refined by performing an optimum (e.g., most favorable among a particular set of results) bit rate error search. To illustrate, as described with reference to FIG. 3, the first read voltage and the offset value may be used to determine an initial test read voltage that may be used to begin a search for a value to be assigned to the second read voltage.

The method 1000 may also include, after the full CVD analysis is performed or after the QCVD analysis is performed, storing updated read voltages based on results of whichever CVD analysis (e.g., a full CVD analysis or a QCVD analysis) was performed and updating a CVD time tag for the results, at 1016. The CVD time tag may be used, for example, to determine when a threshold number of QCVD analysis operations have been performed since a previous full CVD analysis.

Accordingly, the method 1000 enables selective implementation of a full CVD analysis operation or a QCVD analysis operation based on factors such as usage history of the data storage device, a number of QCVD analysis operation performed since a previous full CVD analysis operation was performed, availability of resources of the data storage device, other factors, or a combination thereof. The QCVD analysis operations described herein (such as the method 400 of FIG. 4, the method 500 of FIG. 5 and the method 900 of FIG. 9) are faster and less resource intensive than the full CVD analysis operation. Thus, the method 1000 enables updating of read voltages in a manner that is faster and more efficient at some times (e.g., when the QCVD analysis process is used) and updating of read voltages in a manner that is slower but more thorough at other times (e.g., when the full CVD analysis process is used).

Although various components depicted herein are illustrated as block components and described in general terms, such components may include one or more microprocessors, state machines, or other circuits configured to enable the read voltage update engine 140 of FIG. 1 initiate determination of a first read voltage for a first page and determination of a second read voltage for a second page by applying an offset value to the first read voltage.

The read voltage update engine 140 may be implemented using a microprocessor or microcontroller programmed to determine a first read voltage for a first page and to determine a second read voltage for a second page by applying an offset value to the first read voltage. In a particular embodiment, the read voltage update engine 140 includes a processor executing instructions that are stored at the non-volatile memory 104. Alternatively, or in addition, executable instructions that are executed by the processor may be stored at a separate memory location that is not part of the non-volatile memory 104, such as at a read-only memory (ROM) or at the memory 152.

In a particular embodiment, the data storage device 102 may be attached or embedded within one or more host devices, such as within a housing of a host communication device. For example, the data storage device 102 may be within a packaged apparatus such as a wireless telephone, a personal digital assistant (PDA), a gaming device or console, a portable navigation device, or other device that uses internal non-volatile memory. However, in other embodiments, the data storage device 102 of FIG. 1 may be implemented in a portable device configured to be selectively coupled to one or more external devices.

The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method of updating a set of read voltages, the method comprising:
in a data storage device including a controller, performing:
determining a first read voltage for a first page of a non-volatile memory;
determining a second read voltage for a second page of the non-volatile memory by applying an offset value to the first read voltage; and
storing data identifying the first read voltage and the second read voltage.

2. The method of claim 1, wherein the non-volatile memory is a Multi-Level Cell (MLC) flash memory device.

3. The method of claim 1, wherein the first page is a lower page and the second page is an upper page.

4. The method of claim 1, wherein determining the first read voltage comprises:
performing a plurality of read operations to read values representative of at least one codeword from the first page, wherein two or more of the plurality of read operations are performed using different test read voltages; and
selecting the first read voltage based on results of the plurality of read operations.

5. The method of claim 4, wherein selecting the first read voltage based on results of the plurality of read operations comprises:
performing a plurality of decode operations, wherein each decode operation is performed using a set of values representative of the at least one codeword generated by a corresponding read operation of the plurality of read operations; and
determining, based on the plurality of decode operations, which of the different test read voltages generated fewest errors in the values representative of the at least one codeword, wherein a test read voltage that generated the fewest errors is selected for use as the first read voltage.

6. The method of claim 4, wherein selecting the first read voltage based on results of the plurality of read operations comprises:
performing a first decode operation using a first set of values representative of the at least one codeword generated by a first read operation of the plurality of read operations;
determining whether the first decode operation is successful based on a number of errors that are correctable, wherein if the first decode operation is successful a test read voltage corresponding to the first read operation is selected for use as the first read voltage; and
if the first decode operation is not successful, performing one or more additional decode operations, wherein each of the one or more additional decode operations uses a different set of values representative of the at least one codeword generated by a corresponding read operation of the plurality of read operations, wherein a particular test read voltage corresponding to a particular read operation that is successful is selected for use as the first read voltage.

7. The method of claim 4, wherein selecting the first read voltage based on results of the plurality of read operations comprises estimating a boundary voltage value based on results of the plurality of read operations, wherein the estimated boundary voltage value is selected for use as the first read voltage.

8. The method of claim 4, wherein each of the plurality of read operations generates values representative of a single codeword.

9. The method of claim 1, further comprising determining the offset value based on a count of read cycles associated with the non-volatile memory, based on a count of write cycles associated with the non-volatile memory, or based on both the count of read cycles and the count of write cycles.

10. The method of claim 1, further comprising determining the offset value based on a lookup table.

11. The method of claim 1, wherein the offset value is a fixed value.

12. The method of claim 1, further comprising:
determining a third read voltage for a third page of the non-volatile memory by applying a second offset value to the first read voltage, wherein the second offset value is different than the offset value; and
storing data identifying the third read voltage.

13. The method of claim 1, further comprising, during a read operation, using the first read voltage to read values from the first page and using the second read voltage to read values from the second page.

14. A data storage device comprising:
a controller; and
a non-volatile memory coupled to the controller,
wherein the controller is configured to determine a first read voltage for a first page of the non-volatile memory, to determine a second read voltage for a second page of the non-volatile memory by applying an offset value to the first read voltage, and to store data identifying the first read voltage and the second read voltage.

15. The data storage device of claim 14, wherein the non-volatile memory is a Multi-Level Cell (MLC) flash memory device.

16. The data storage device of claim 14, wherein the first page is a lower page and the second page is an upper page.

17. The data storage device of claim 14, wherein the controller is configured to determine the first read voltage by:
performing a plurality of read operations to read values representative of at least one codeword from the first page of the non-volatile memory, wherein two or more of the plurality of read operations are performed using different test read voltages; and
selecting the first read voltage based on results of the plurality of read operations.

18. The data storage device of claim 17, wherein the controller is configured to select the first read voltage based on results of the plurality of read operations by:
performing a plurality of decode operations, wherein each decode operation is performed using a set of values representative of the at least one codeword generated by a corresponding read operation of the plurality of read operations; and
determining, based on the plurality of decode operations, which of the different test read voltages generates fewest errors in the values representative of the at least one codeword, wherein a test read voltage that generated the fewest errors is selected for use as the first read voltage.

19. The data storage device of claim 17, wherein the controller is configured to select the first read voltage setting based on results of the plurality of read operations by:
performing a first decode operation using a first set of values representative of the at least one codeword generated by a first read operation of the plurality of read operations;
determining whether the first decode operation is successful based on a number of errors that are correctable, wherein if the first decode operation is successful a test read voltage corresponding to the first read operation is selected for use as the first read voltage; and
if the first decode operation is not successful, performing one or more additional decode operations, wherein each of the one or more additional decode operations uses a different set of values representative of the at least one codeword generated by a corresponding read operation of the plurality of read operations, wherein a particular test read voltage corresponding to a particular read operation that is successful is selected for use as the first read voltage.

20. The data storage device of claim 17, wherein the controller is configured to select the first read voltage based on results of the plurality of read operations by estimating a boundary voltage value based on results of the plurality of read operations, wherein the estimated boundary voltage value is selected for use as the first read voltage.

21. The data storage device of claim 17, wherein each of the plurality of read operations generates values representative of a single codeword.

22. The data storage device of claim 14, wherein the controller is further configured to determine the offset value based on a count of read cycles associated with the non-volatile memory, based on a count of write cycles associated with the non-volatile memory, or based on both the count of read cycles and the count of write cycles.

23. The data storage device of claim 14, wherein the controller is further configured to determine the offset value based on a lookup table.

24. The data storage device of claim 14, wherein the offset value is a predetermined fixed value.

25. The data storage device of claim 14, wherein the controller is further configured to determine a third read voltage for a third page of the non-volatile memory by applying an second offset value to the first read voltage, wherein the second offset value is different than the offset value.

26. The data storage device of claim 14, wherein the controller is further configured to, during a read operation, use the first read voltage to read values from the first page and use the second read voltage to read values from the second page.

27. A method of updating a set of read voltages, the method comprising:
in a data storage device including a controller and a non-volatile memory, performing:
determining a first read voltage for a first page of the non-volatile memory;
determining a first test read voltage for a second page of the non-volatile memory by applying an offset value to the first read voltage;
performing a first read operation, using the first test read voltage, to read first values representative of at least one codeword from the second page of the non-volatile memory;
performing a first decode operation using the first values representative of the at least one codeword;
determining whether the first decode operation is successful based on a number of errors that are correctable by the first decode operation; and
when the first decode operation is successful, storing the first test read voltage as a second read voltage for the second page of the non-volatile memory.

28. The method of claim 27, further comprising:
when the first decode operation is not successful:
performing one or more additional read operations to read values representative of the at least one codeword from the second page of the non-volatile memory, wherein each of the one or more additional read operations uses a corresponding test read voltage;
performing one or more additional decode operations, wherein each of the one or more additional decode operations uses a set of values representative of the at least one codeword generated by a corresponding read operation of the one or more of read operations;
identifying a particular decode operation of the one or more additional decode operations that is successful based on the number of errors that are correctable by the particular decode operation; and
storing a particular test read voltage corresponding to the particular decode operation as the second read voltage for the second page of the non-volatile memory.

29. A data storage device comprising:
a controller; and
a non-volatile memory coupled to the controller,
wherein the controller is configured to determine a first read voltage for a first page of the non-volatile memory, determine a first test read voltage for a second page of the non-volatile memory by applying an offset value to the first read voltage, perform a first read operation to read first values representative of at least one codeword from the second page of the non-volatile memory, perform a first decode operation using the first values representative of the at least one codeword, determine whether the first decode operation is successful based on a number of errors that are correctable by the first decode operation, and, when the first decode operation is successful, store the first test read voltage as a second read voltage for the second page of the non-volatile memory.
